(19) United States
(12) Patent Application Publication
(10) Pub. No.: US 2015/0128863 A1
(43) Pub. Date: May 14, 2015

(54) MECHANISMS FOR FURNACE APPARATUS AND WAFER BOAT

(71) Applicant: TAIWAN SEMICONDUCTOR MANUFACTURING CO., LTD., HSIN-CHU (TW)

(72) Inventors: Yi-Chang LIN, Hsinchu City (TW); Hsin-Hong LIN, Zhubei City (TW)

(73) Assignee: TAIWAN SEMICONDUCTOR MANUFACTURING CO., LTD., HSIN-CHU (TW)

(21) Appl. No.: 14/079,803

(22) Filed: Nov. 14, 2013

(51) Int. Cl. H01L 21/673; C23C 16/458

(52) U.S. Cl. CPC H01L 21/67309; H01L 21/67306; C23C 16/4583
USPC 118/728; 211/41.18

(57) ABSTRACT

Embodiments of mechanisms of a furnace apparatus having a wafer boat are provided. The wafer boat includes a base plate and a support rod extended from the base plate. The wafer boat also includes a support finger including a finger body extended from the support rod and a curved end portion extended from the finger body. The wafer boat further includes a top plate supported on the support rod. A width of the support rod exceeds that of the support finger.

### BACKGROUND

Semiconductor devices are used in a variety of electronic applications, such as personal computers, cell phones, digital cameras, and other electronic equipment. Semiconductor devices are typically fabricated by sequentially depositing insulating or dielectric layers, conductive layers, and semiconductive layers of material over a semiconductor substrate, and patterning the various material layers using lithography to form circuit components and elements thereon. Many integrated circuits are typically manufactured on a single semiconductor wafer, and individual dies on the wafer are singulated by sawing between the integrated circuits along a scribe line. The individual dies are typically packaged separately, in multi-chip modules, or in other types of packaging, for example.

Chemical vapor deposition (CVD) processes are widely used to form layers of materials on a semiconductor wafer. CVD processes include thermal deposition processes, in which a gas is reacted with the heated surface of a semiconductor wafer substrate. As well as plasma-enhanced CVD processes, a gas is subjected to electromagnetic energy in order to transform the gas into a more reactive plasma. Forming a plasma can lower the temperature required to deposit a layer on the wafer substrate, to increase the rate of layer deposition, or both. Other CVD processes include APCVD (atmospheric pressure chemical vapor deposition), and LPCVD (low pressure chemical vapor deposition). While APCVD systems have high equipment throughput, good uniformity and the capability to process large-diameter wafers, APCVD systems consume large quantities of process gas and often exhibit poor step coverage. Currently, LPCVD is used more often than APCVD because of its lower cost, higher production throughput and superior film properties. LPCVD is commonly used to deposit nitride, TEOS oxide and polysilicon films on wafer surfaces for front-end-of-line (FEOL) processes.

In general, LPCVD processes are applied in a furnace including a wafer boat and a quartz tube. Many wafers are disposed in the wafer boat. During LPCVD processes, the wafer boat with wafers is transported into the quartz tube. However, some particles can fall on the wafers from the wafer boat, and therefore the wafers are contaminated by the particles. Therefore, there are challenges to minimizing particulate contamination of the wafers during processing.

### BRIEF DESCRIPTION OF THE DRAWINGS

For a more complete understanding of the present disclosure, and the advantages of the present disclosure, reference is now made to the following descriptions taken in conjunction with the accompanying drawings:

FIG. 1 is a schematic view of a chemical vapor deposition system in accordance with some embodiments of the disclosure.

FIG. 2 is a schematic view of the furnace apparatus in accordance with some embodiments of the disclosure.

FIG. 3 is a side view of the wafer boat containing wafers in accordance with some embodiments of the disclosure.

FIG. 4 is a cross-sectional view of the line AA of FIG. 3 in accordance with some embodiments of the disclosure.

FIG. 5 is a front view of the wafer boat in accordance with some embodiments of the disclosure.

FIG. 6 is an enlarged view of the wafer boat of FIG. 5 in accordance with some embodiments of the disclosure.

FIGS. 7A and 7B are cross-sectional views of the BB line in FIG. 6 in accordance with some embodiments of the disclosure.

### DETAILED DESCRIPTION

The making and using of various embodiments of the disclosure are discussed in detail below. It should be appreciated, however, that the various embodiments can be embodied in a wide variety of specific contexts. The specific embodiments discussed are merely illustrative, and do not limit the scope of the disclosure.

It is to be understood that the following disclosure provides many different embodiments, or examples, for implementing different features of the disclosure. Specific examples of components and arrangements are described below to simplify the present disclosure. These are, of course, merely examples and are not intended to be limiting. Various features may be arbitrarily drawn in different scales for the sake of simplicity and clarity. Furthermore, the formation of a first feature over or on a second feature in the description may include embodiments in which the first and second features are formed in direct or indirect contact.

Some variations of the embodiments are described. Throughout the various views and illustrative embodiments, like reference numbers are used to designate like elements. It is understood that additional steps can be provided before, during, and after the method, and some of the steps described can be replaced or eliminated for other embodiments of the method.

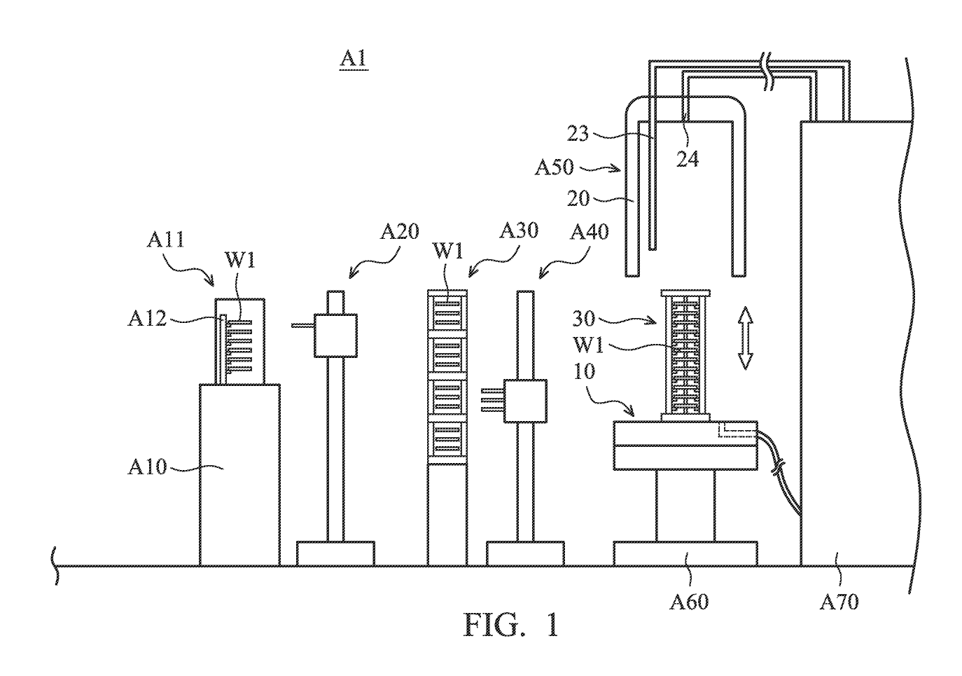

The present disclosure contemplates a wafer boat which is suitable for holding multiple wafers in a reaction furnace and reducing particle generation during processing of the wafers. FIG. 1 is a schematic view of a chemical vapor deposition system A1 in accordance with some embodiments of the disclosure. The chemical vapor deposition system A1 includes a cassette stage A10, a first wafer transfer robot A20, a wafer rack A30, a second wafer transfer robot A40, a furnace apparatus A50, an elevating device A60 and a gas tank A70. The cassette stage A10 is for a wafer pod A11 disposed on the cassette stage A10.

The wafer pod A11 has a cassette A12 for containing wafers W1. The first wafer transfer robot A20 transports the wafer W1 in the cassette A12 to the wafer rack A30. The second wafer transfer robot A40 transports the wafers W1 in the wafer rack A30 to the furnace apparatus A50. In general, the first wafer transfer robot A20 transports one wafer W1 at the same time. The second wafer transfer robot A40 transports one to five wafers W1 at the same time to increase the transport efficiency.

The furnace apparatus A50 includes a base 10, a reaction furnace 20, and a wafer boat 30. The base 10 is removably mounted on the reaction furnace 20. The base 10 is disposed on the elevating device A60, and the wafer boat 30 is disposed on the base 10.

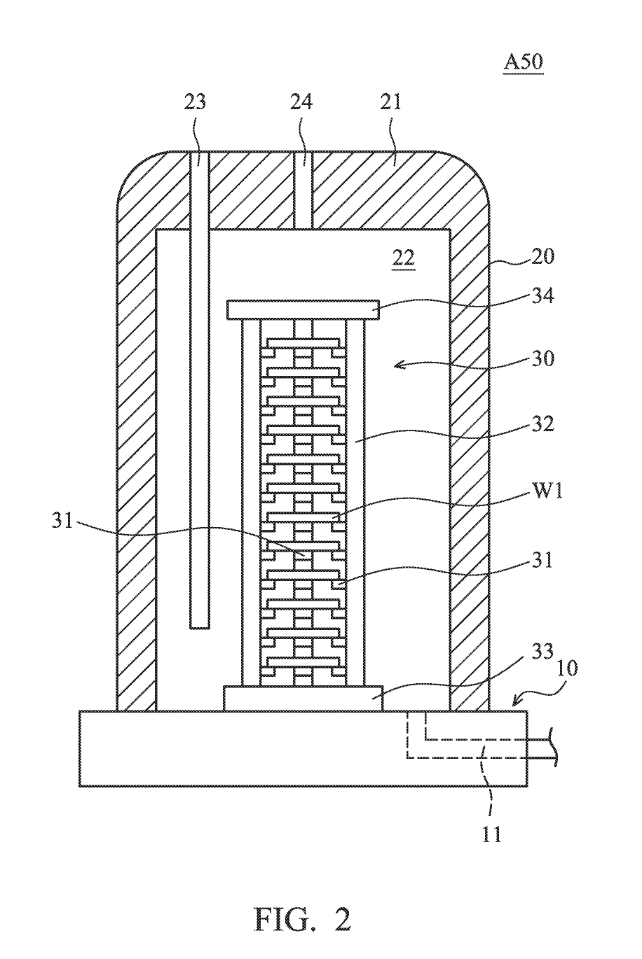

In some embodiments, the furnace apparatus A50 is a LPCVD (low pressure chemical vapor deposition) furnace. When the LPCVD processes are started, the elevating device A60 raises the base 10 to the reaction furnace 20. FIG. 2 is a schematic view of the furnace apparatus A50 in accordance with some embodiments of the disclosure. As shown in FIG. 2, LPCVD processes are carried out in the furnace apparatus A50.

The reaction furnace 20 has a reaction body 21, a reaction chamber 22, a gas inlet tube 23, and a gas inlet opening 24. The reaction chamber 22 is formed in the reaction body 21. The gas inlet tube 23 is extended downward through the reaction body 21 into the reaction chamber 22. The gas inlet opening 24 is located at the top center of the reaction body 21. The gas tank A70 transports reaction gases into the reaction chamber 22 via the gas inlet tube 23 and the gas inlet opening 24.

In some embodiments, the base 10 includes a gas outlet 11 for distributing exhaust gases from the reaction chamber 22. The gas outlet 11 may be located on the opposite side of the wafer boat 30 with respect to the gas inlet tube 23 to facilitate a more uniform flow of the reaction gases throughout the reaction chamber 22.

The wafer boat 30 is supported on the base 10 and contained in the reaction chamber 22 during LPCVD processes. Wafers W1 are held by the wafer boat 30. The wafer boat 30 is moved into the reaction chamber 22 or out of the reaction chamber 22 by the base 10 and the elevating device A60.

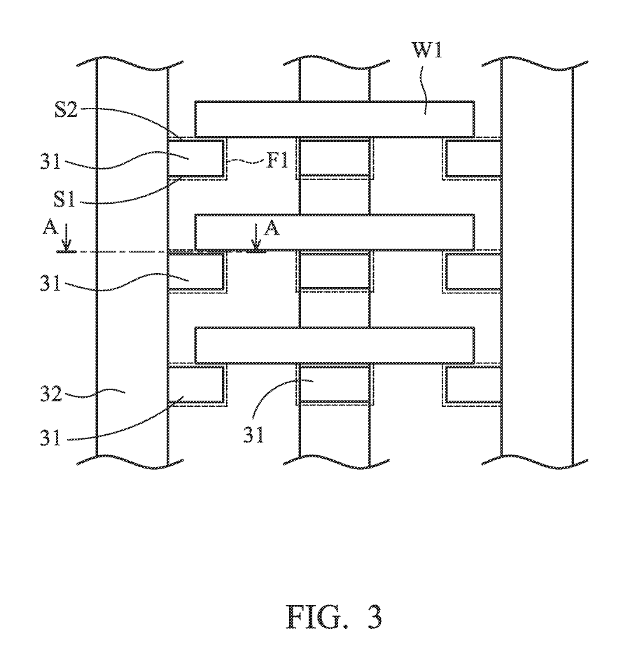

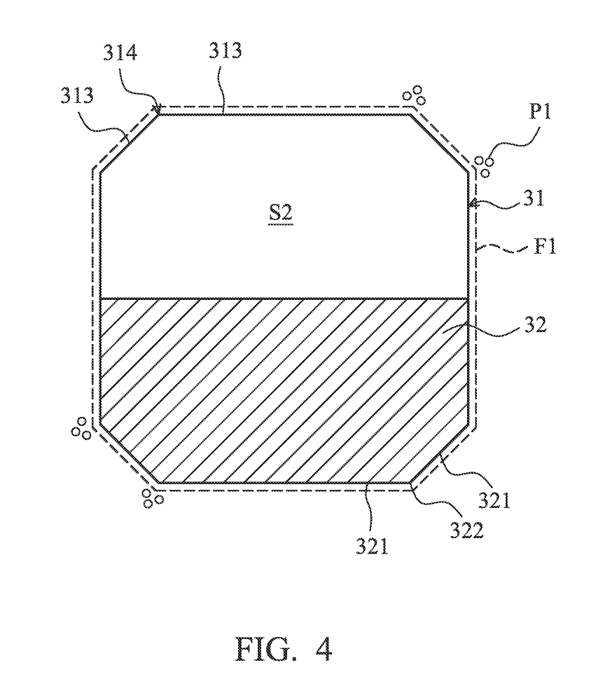

FIG. 3 is a side view of the wafer boat 30 containing wafers W1 in accordance with some embodiments of the disclosure. FIG. 4 is a cross-sectional view of the line AA of the FIG. 3 in accordance with some embodiments of the disclosure. As shown in FIGS. 2 and 3, the wafer boat 30 includes support fingers 31 and support rods 32. The support fingers 31 are extended from the support rods 32. Each of the wafers W1 is supported on the support fingers 31.

During LPCVD processes carried out in the furnace apparatus A50, wafers W1 are processed in batches in order to maintain high wafer throughput. Process gases are introduced into the reaction furnace 20 through the gas inlet tube 23 and/or the gas inlet opening 24, and the wafers W1 are heated to facilitate deposition of chemical species from the process gases, on to the wafers W1. Exhaust gases are evacuated from the base 10 through the gas outlet 11.

In some embodiments, the wafer boat 30 is made of quartz, silicon carbide or silicon. To simplify the fabrication of the wafer boat 30, the support fingers 31 and the support rods 32 have flat walls 313 and 321, and therefore sharp corners 314 and 322 are formed on the support fingers 31 and the support rods 32.

As shown in FIG. 4, a film F1 is also formed on the flat walls 313 and 321 by the LPCVD processes, a lower surface S1 and an upper surface S2 of the support fingers 31. A force applied to the film F1 near the sharp corners 314 and 322 due to the change of the volumes of the film F1 and the wafer boat 30 by the temperature difference, and a part of the film F1 is easily peeling from the sharp corners 314 and 322 and forming particles P1. Some of the particles P1 may fall down to the wafers W1 and contaminate of the wafers during processing.

Further, as shown in FIGS. 3 and 4, the width of the support rod 32 is equal to that of the support finger 31, and the area of the upper surface S2 is greater or substantially equal to the area of a cross section of the support rod 32. Particles P1 may be generated by the friction between the upper surface S2 and the wafer W1. Therefore, there are more particles P1 generated since the area of the wafer W1 in contact with the upper surface S2 is larger.

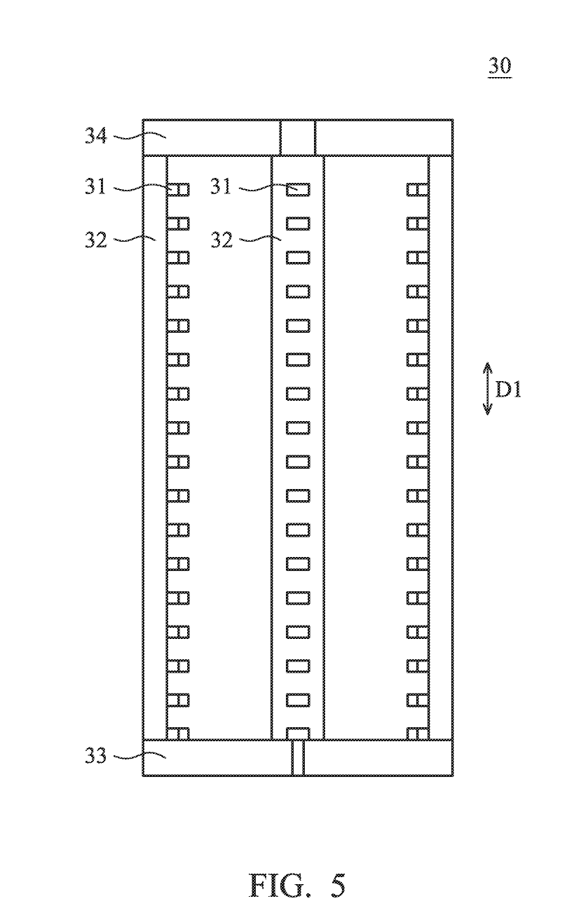

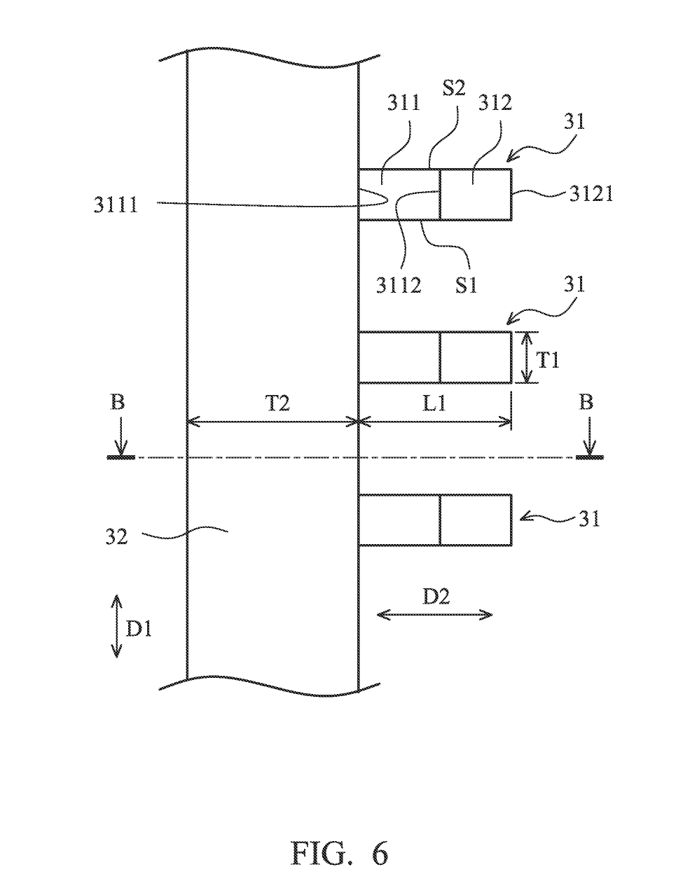

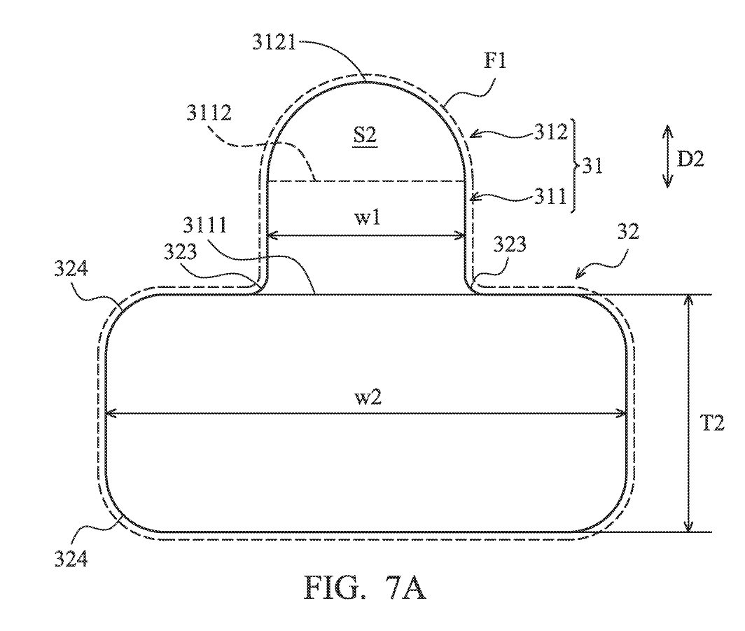

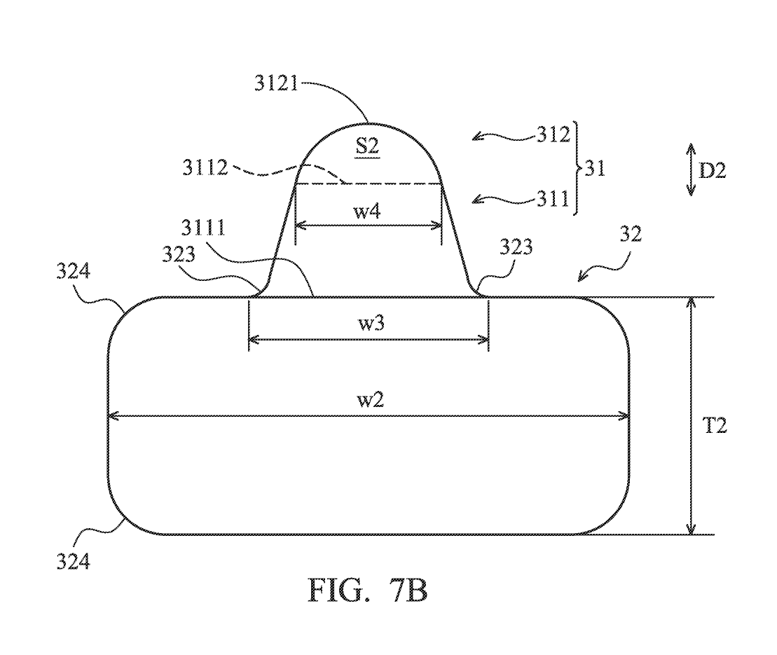

FIG. 5 is a front view of the wafer boat 30 in accordance with some embodiments of the disclosure. FIG. 6 is an enlarged view of FIG. 5 in accordance with some embodiments of the disclosure. FIG. 7A is a cross-sectional view of the BB line in FIG. 6 in accordance with some embodiments of the disclosure. In some embodiments, the cross-section of the wafer boat 30 in FIG. 7A is perpendicular to the longitudinal direction D1. In some embodiments, the wafer boat 30 having the dimensions is specifically adapted to support 200 mm wafers. However, it is understood that the dimensions of the wafer boat 30 can be adapted to support wafers of larger or smaller size, as desired. The wafer boat 30 may be constructed of quartz, silicon carbide (SiC), silicon (Si) or other corrosion-resistant and heat-resistant materials known by those skilled in the art.

The wafer boat 30 further includes a base plate 33, and a top plate 34. The base plate 33 is disposed on the base 10 as shown in FIG. 2. In some embodiments, the base plate 33 is a generally flat, circular base plate. The elongated support rods 32 are extended from the base plate 33. The support rods 32 are in parallel with and spaced apart from each other. The top plate 34 is a generally flat, circular top plate, and supported on the upper ends of the support rods 32.

The support fingers 31 are extended from each support rod 32. In some embodiments, the support rods 32 are extended along a longitudinal direction D1. The support fingers 31 are extended along a transverse direction D2 perpendicular to the longitudinal direction D1. The support fingers 31 are in parallel with and spaced apart from to each other. In some embodiments, the distance between two adjacent support fingers 31 is in a range from about 1.5 mm to about 10 mm. Each support fingers 31, which extends from each support rod 32 at a particular height, is disposed in the same generally horizontal plane as the other support fingers 31 that extend from the other support rod 32, respectively, at that height.

In some embodiments, the support fingers 31 are plate structures. Each support finger 31 has the lower surface S1 and the upper surface S2. The lower surface S1 and the upper surface S2 are in generally parallel to each other and perpendicular to the longitudinal direction D1. Each of the wafers W1 is supported on the upper surface S2. In some embodiments, the roughness of the upper surface S2 is in a range from about 1 um to about 5 um. For example, the roughness of the upper surface S2 is about 3 um. Therefore, the wafers W1 contaminated by the particles are decreased, since the film F1 is not easily peeing from the upper surface S2 having the roughness due to the friction between the upper surface S2 and the wafer W1.

For example, if the roughness of the upper surface S2 is lower than 0.5 um, the upper surface S2 is too smooth. The film F1 is easily peeing from the upper surface S2 due to the friction between the upper surface S2 and the wafer W1. Further, if the roughness of the upper surface S2 is greater than 10 m, there are many tips protruded from the upper surface S2, and therefore the film F1 is easily peeing from the upper surface S2.

In some embodiments, the wafer boat 1 is designed to support 200 mm wafers. The finger length L1 of the support finger 31 is in a range from about 5 mm to about 10 mm. For example, the finger length L1 is about 6 mm or about 8 mm. The finger thickness T1 of the support finger 31 is in a range from about 1.5 mm to about 3 mm. For example, the finger thickness T1 is about 2 mm. However, the finger length L1 and the finger thickness T1 may vary depending on the diameter of wafers W1 to be supported on the wafer boat 30.

Each support finger 31 includes a finger body 311 and a curved end portion 312. The finger body 311 is extended from the support rod 32. The curved end portion 312 is extended from the finger body 311. The finger body 311 is located between the support rod 32 and the curved end portion 312.

The area of the upper surface S2 of the support finger 31 is in a range from about 31 mm² to 36 mm². The area of the cross-section of the support rod 32 exceeds that of the support finger 31. In some embodiments, the area of the cross-section of the support rod 32 exceeds at least two times or three times that of the support finger 31. In the other words, the area of a cross-section of the support rod 32 is at least two or three times greater than the area of the upper surface S2.

The width w2 of the support rod 32 is greater than the width w1 of the support finger 31. As shown in FIG. 7A, the width w2 of the support rod 32 is greater than the width w1 of the finger body 311. In some embodiments, the width w2 of the support rod 32 is at least two times or three times greater than the width w1 of the finger body 311. The width w1 of the finger body 311 is in a range from about 3 mm to 7 mm. The width w2 of the support rod 32 is in a range from about 14 mm to 18 mm. In some embodiments, the width w1 and the width w2 are defined as the widths along a direction perpendicular to the longitudinal direction D1 and the transverse direction D2. In addition, the thickness T2 of the support rod 32 is in a range from about 4 mm to 12 mm.

Since the support finger 31 has a narrow width, the area of the wafer W1 in contact with the upper surface S2 is smaller. Therefore, the particles generated by the friction between the upper surface S2 and the wafer W1 are lesser.

As shown in FIGS. 6 and 7A, the finger body 311 has a proximal side 3111 and a distal side 3112. The proximal side 3111 is attached to or continuous with the support rod 32. The distal side 3112 is spaced from the proximal side 3111. The curved end portion 312 is extended from the distal side 3112.

The curved end portion 312 has a curved edge 3121 spaced from the distal side 3112 of the finger body 311. The curved edge 3121 has a curvature in a range from about 0.2 mm̂-1 to about 0.66 mm̂-1. For example, the curvature of the curved edge 3121 is about 0.33 mm̂-1 or about 0.5 mm̂-1. Namely, in some embodiments, the curved end portion 312 is a semicircle or an arch shape. The finger body 311 is rectangular, and the width w1 of the finger body 311 is equal to the width of the curved end portion 312.

Further, the support rod 32 has fillets 323 and 324 extending along the longitudinal direction D1. The fillet 323 connects to the finger body 311. The fillets 323 and 324 have curvatures in a range from about 0.25 mm⁻¹ to about 1 mm⁻¹.

A force is applied to the film F1 near the fillets 323 and 324 and the curved end portion 312 due to the change of the volumes of the film F1 and the wafer boat 30 by the temperature difference. However, the fillets 323 and 324 and the curved end portion 312 are smooth and curved, and the force applied on the film F1 is less. Therefore, the film F1 is not easily peeling from the support finger 31 and the support rod 32, the particles formed by the film F1 is less, and the wafers contaminated by the particles is decreased.

FIG. 7B is a cross-sectional view of the BB line in FIG. 6 in accordance with some embodiments of the disclosure. In some embodiments, the finger body 311 is a trapezoid or a trapezoid-like shape. The proximal side 3111 of the finger body 311 has a first width w3 adjacent to the support rod 32, and the distal side 3112 of the finger body 311 has a second width w4 adjacent to the curved end portion 312. The first width w3 exceeds the second width w4. The force applied on the film F1 is further smaller in the described structure of the support finger 31.

Embodiments of mechanisms for a furnace apparatus having a wafer boat are provided. The wafer boat has a support rod and a support finger extended from the support rod. The width of the support rod exceeds that of the support finger. The support finger has a curved end portion. Therefore, the wafer boat is suitable for holding multiple wafers in a reaction furnace and reducing particle generation during processing of the wafers.

In some embodiments, a wafer boat is provided. The wafer boat includes a base plate and a support rod extending from the base plate. The wafer boat also includes a support finger including a finger body extended from the support rod and a curved end portion extended from the finger body. The wafer boat further includes a top plate supported on the support rod. The support rod has a width which exceeds that of the support finger.

In some embodiments, a wafer boat is provided. The wafer boat includes a base plate and a support rod extended from the base plate. The wafer boat also includes a support finger including a finger body extended from the support rod and a curved end portion extended from the finger body. The wafer boat further includes a top plate supported on the support rod. The support finger has an upper surface, and the width of the support rod exceeds two times that of the upper surface. An area of a cross-section of the support rod exceeds two times that of the upper surface.

In some embodiments, a furnace apparatus is provided. The furnace apparatus includes a base and a wafer boat. The wafer boat includes a base plate and a support rod extended from the base plate. The wafer boat also includes a support finger including a finger body extended from the support rod and a curved end portion extended from the finger body. The wafer boat further includes a top plate supported on the support rod. The furnace apparatus also includes a reaction furnace disposed over the wafer boat and having a reaction chamber. Each of the support fingers has an upper surface for a wafer disposed thereon, and the width of the support rod exceeds two times that of the upper surface. The wafer boat is moved into the reaction chamber or out of the reaction chamber by the base.

Although embodiments of the present disclosure and their advantages have been described in detail, it should be understood that various changes, substitutions and alterations can be made herein without departing from the spirit and scope of the disclosure as defined by the appended claims. For example, it will be readily understood by those skilled in the art that many of the features, functions, processes, and materials described herein may be varied while remaining within the scope of the present disclosure. Moreover, the scope of the present application is not intended to be limited to the particular embodiments of the process, machine, manufacture, composition of matter, means, methods and steps described in the specification. As one of ordinary skill in the art will readily appreciate from the disclosure of the present disclosure, processes, machines, manufacture, compositions of matter, means, methods, or steps, presently existing or later to be developed, that perform substantially the same function or achieve substantially the same result as the corresponding embodiments described herein may be utilized according to the present disclosure. Accordingly, the appended claims are intended to include within their scope such processes, machines, manufacture, compositions of matter, means, methods, or steps.

What is claimed is:

1. A wafer boat, comprising:
a base plate;
a support rod extended from the base plate;
a support finger comprising:
a finger body extended from the support rod; and
a curved end portion extended from the finger body; and
a top plate supported on the support rod,
wherein a width of the support rod exceeds that of the support finger.

2. The wafer boat as claimed in claim 1, wherein the curved end portion has a curved edge having a curvature in a range from about 0.2 to about 0.66.

3. The wafer boat as claimed in claim 1, wherein the finger body is rectangular, the curved end portion is a semicircle or an arch shape, and a width of the finger body is equal to a width of the curved end portion.

4. The wafer boat as claimed in claim 1, wherein the finger body is a trapezoid or a trapezoid-like shape having a first width adjacent to the support rod and a second width adjacent to the curved end portion, wherein the first width exceeds the second width.

5. The wafer boat as claimed in claim 1, wherein the support finger has an upper surface, and a roughness of the upper surface is in a range from about 1 um to about 5 um.

6. The wafer boat as claimed in claim 1, wherein the support rod is extended along a longitudinal direction, and the support finger is extended perpendicular to the longitudinal direction.

7. The wafer boat as claimed in claim 6, wherein the support rod has a fillet extended along the longitudinal direction and connected to the finger body.

8. A wafer boat, comprising:
a base plate;
a support rod extended from the base plate;
a support finger comprising:
a finger body extended from the support rod; and
a curved end portion extended from the finger body; and
a top plate supported on the support rod,
wherein the support finger has an upper surface, and a width of the support rod exceeds two times that of the upper surface,
wherein an area of a cross-section of the support rod exceeds two times that of the upper surface.

9. The wafer boat as claimed in claim 8, wherein the curved end portion has a curved edge having a curvature in a range from about 0.2 to about 0.66.

10. The wafer boat as claimed in claim 8, wherein the finger body is rectangular, the curved end portion is a semicircle or an arch shape, and a width of the finger body is equal to a width of the curved end portion.

11. The wafer boat as claimed in claim 8, wherein the finger body is a trapezoid or a trapezoid-like shape having a first width adjacent to the support rod and a second width adjacent to the curved end portion, wherein the first width exceeds the second width.

12. The wafer boat as claimed in claim 8, wherein a roughness of the upper surface is in a range from about 1 um to about 5 um.

13. The wafer boat as claimed in claim 8, wherein the support rod is extended along a longitudinal direction, and the support finger is extended perpendicular to the longitudinal direction.

14. The wafer boat as claimed in claim 13, wherein the support rod has a fillet extended along the longitudinal direction and connected to the finger body.

15. A furnace apparatus, comprising:
a base;
a wafer boat, comprising:
a base plate disposed on the base;
a support rod disposed on the base plate;
a support finger comprising:
a finger body extended from the support rod; and
a curved end portion extended from the finger body; and
a top plate supported on the support rod,
a reaction furnace, disposed over the wafer boat, having a reaction chamber;
wherein each of the support fingers has an upper surface for a wafer disposed thereon, and a width of the support rod exceeds two times that of the upper surface,
wherein the wafer boat is moved into the reaction chamber or out of the reaction chamber by the base.

16. The furnace apparatus as claimed in claim 15, wherein a distance between two adjacent support fingers is in a range from about 1.5 mm to about 10 mm.

17. The furnace apparatus as claimed in claim 15, wherein the curved end portion has a curved edge having a curvature in a range from about 0.2 to about 0.66.

18. The furnace apparatus as claimed in claim 15, wherein a roughness of the upper surface is in a range from about 1 um to about 5 um.

19. The furnace apparatus as claimed in claim 15, wherein the support rod is extended along a longitudinal direction, and the support finger is extended perpendicular to the longitudinal direction.

20. The furnace apparatus as claimed in claim 19, wherein the support rod has a fillet extended along the longitudinal direction and connected to the finger body.
